(19) United States
(12) Patent Application Publication
(10) Pub. No.: US 2025/0374696 A1
(43) Pub. Date: Dec. 4, 2025

(54) SINGLE PHOTON AVALANCHE DIODE FOR EXTREME ULTRAVIOLET PHOTON DETECTION AND RELATED METHODS

(71) Applicant: Taiwan Semiconductor Manufacturing Co., Ltd., Hsinchu (TW)

(72) Inventors: Hao-Ming CHANG, Hsinchu (TW); Cheng-Kuang CHEN, Hsinchu (TW); Kuo-Chin HUANG, Hsinchu (TW); Chih-Chiang TU, Hsinchu (TW); Chue-San YOO, Hsinchu (TW)

(21) Appl. No.: 18/679,046

(22) Filed: May 30, 2024

(51) Int. Cl. H01L 27/146; G03F 1/84

(52) U.S. Cl. CPC H10F 39/8067; G03F 1/84; H10F 39/018; H10F 39/024; H10F 39/028; H10F 39/18; H10F 39/805; H10F 39/807; H10F 39/809

(57) ABSTRACT

A photon detector device and method are disclosed. The device includes a substrate with an isolation structure, guard ring, sensor node, and common node on the front side, an isolation extension structure extending from the back side to the front side, and a multilayer reflector on the front side. The method includes doping the substrate, forming the various structures, and using the device to detect a photon of extreme ultraviolet wavelength by generating an avalanche current in response to the photon.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B and 1C are diagrammatic plan views of a portion of an IC device according to embodiments of the present disclosure.

FIG. 2 is a layout view of a region of the IC device according to various aspects of the present disclosure.

FIGS. 3A-3D are diagrammatic views of detector pixels in accordance with various embodiments.

FIG. 4 is a diagrammatic cross-sectional side view of a detector device in accordance with various embodiments.

FIG. 5 is a detailed side view of a detector device in accordance with various embodiments.

FIGS. 6A and 6B are detailed diagrammatic views of a conductive deep isolation trench in accordance with various embodiments.

FIG. 7A-7N are views of various embodiments of an IC device of at various stages of fabrication according to various aspects of the present disclosure.

FIG. 8 is a diagrammatic view of a system for detecting an EUV photon in accordance with various embodiments.

FIG. 9 is a flowchart of a method of forming an IC device in accordance with various embodiments.

FIG. 10 is a flowchart of a method of detecting a photon in accordance with various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms indicative of relative degree, such as “about,” “substantially,” and the like, should be interpreted as one having ordinary skill in the art would in view of current technological norms.

The terms “first,” “second,” “third” and so on may be used herein to describe a sequence of events or sequential order of elements but may be exchanged or varied in some contexts. For example, a second layer may be formed on (e.g., sequentially after) a first layer, but in some contexts the first layer may be referred to as a “second layer,” “third layer,” “fourth layer” or the like, and the second layer may be referred to as a “first layer,” “third layer,” “fourth layer,” or the like.

The term “surrounds” may be used herein to describe a structure that fully or partially encloses another element or structure, for example, in three dimensions. For example, a first structure may “surround” a second structure on four lateral sides (e.g., left, right, front and back) without surrounding the second structure on two vertical sides (e.g., top and bottom). In other example, the first structure may wrap partially around the second structure, for example, by wrapping around three sides (e.g., top, front and back) while leaving other sides (e.g., left, right and bottom) exposed.

Source/drain region(s) may refer to a source or a drain, individually or collectively dependent upon the context.

The present disclosure is generally related to semiconductor devices, and more particularly to backside illuminated (BSI) single photon avalanche diodes (SPADs) for extreme ultraviolet (EUV) photon detection and related methods of fabrication and use.

As semiconductor manufacturing technology advances towards an EUV generation, challenges in mask inspection increase dramatically, making it difficult to use deep ultraviolet (DUV) laser sources as an inspection light source. The DUV source faces three main difficulties, including limited resolution, inability to detect phase defects and inability to perform pellicle inspection.

First, the resolution of DUV is limited by physical formula which is proportional to its wavelength. Namely, EUV wavelengths of about 13.5 nm provide about 14 times higher resolution than DUV wavelengths. Second, DUV cannot reveal phase defects inside a reflective multilayer of a mask or “photomask,” which can cause pattern distortion on photoresist on a wafer during exposure. Third, a silicon material selected as a pellicle thin film to increase transmission level in the EUV regime absorbs DUV wavelengths, limiting development in particle prevention. High-volume manufacturing (HVM) may not be achieved if these challenges are not resolved.

Currently, EUV source power for actinic inspection is continually improving. However, EUV sensor development is still limited. Inspection devices, such as time delay integration (TDI) sensors, charge coupled device (CCD) sensors and complementary metal oxide semiconductor (CMOS) device sensors have focused on visible wavelengths or infrared wavelengths to address growing demand in automotive technology, such as for self-driving vehicles. In many sensors for EUV, signal-to-noise ratio (SNR) is limited, which interferes with defect detection or so-called “defect inspection.” The poor SNR affects sensitivity of a detection algorithm, and if the sensitivity is tightened to compensate for the poor SNR, false positives in defect detection increase due to the noise, such that likelihood of inspection failure is increased.

In embodiments of the disclosure, a detector device with high resolution is provided. A single photon CMOS device, such as a SPAD, is provided that can detect a single EUV photon with significant noise reduction by the device and associated analog setting selection. The device can serve as an EUV photon detector for an inspection system and may additionally serve as a monitoring sensor for verifying source power intensity and/or depth of focus on a mirror which can boost real-time monitoring capability.

The detector device is associated with a variety of benefits. The detector device can enable development of ultrahigh resolution imaging in EUV inspection systems. Utilizing SPAD photon counting can mitigate against gain noise and circuit noise due to detector response being binarized. Most SPADs have a tradeoff between efficiency and wider bandwidth, however in the embodiments, the EUV SPAD operates on EUV light having bandwidth of 13.5 nm, which can increase efficiency. A multifunction system can use the SPAD-based detector to include both detection and monitoring functionalities. It should be noted that, although the embodiments are described with reference to EUV inspection and monitoring, the SPAD and detector devices described herein may also be used in fields such as deep-space laser communication, microscopy, astronomy and other similar applications.

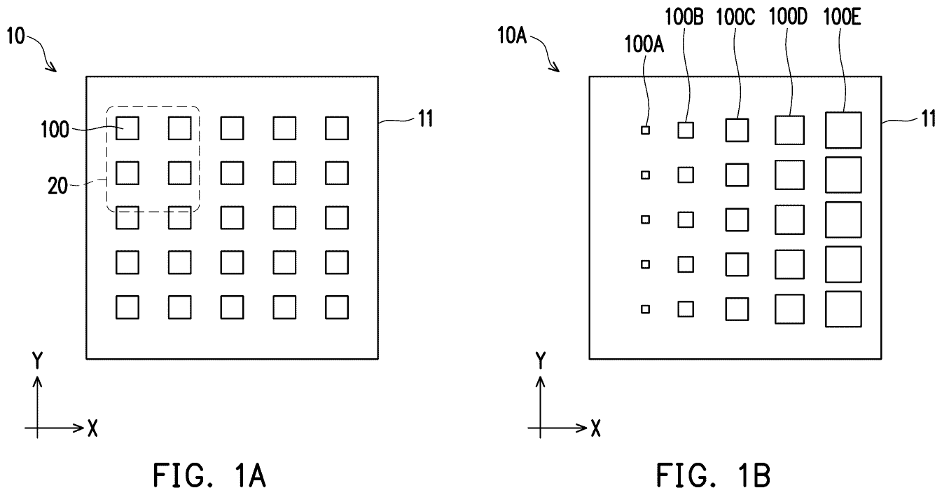

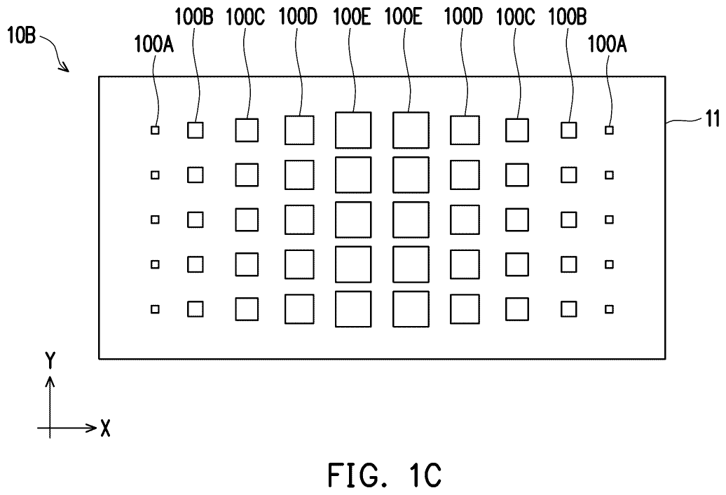

FIGS. 1A, 1B and 1C are diagrammatic plan views of a portion of a detection or detector device 10 in accordance with various embodiments. FIGS. 1A-1C depict views in an X-Y plane.

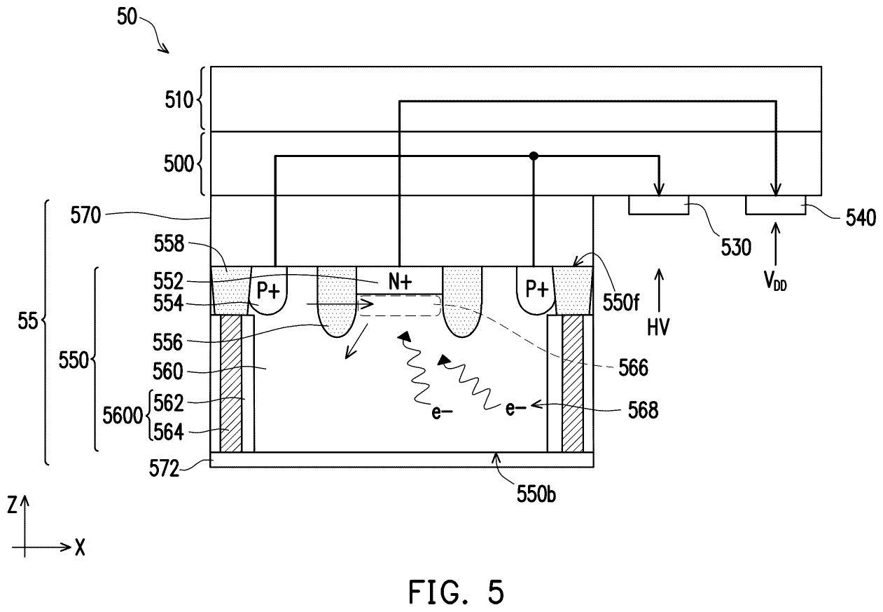

Referring to FIG. 1A, single-photon avalanche diodes (SPADs) 100 are positioned on and/or in a substrate 11 of the detector device 10, which may also be referred to as an image sensor 10. In some embodiments, the detector device 10 or image sensor 10 is a sensing region of an integrated device. For example, the sensing region may occupy a portion of the substrate 11 and other circuitry (e.g., driving and/or processing) circuitry may occupy another adjacent portion(s) of the substrate 11. The substrate 11 may include one or more layers doped with dopants of a first and/or second conductivity type, e.g., p type and/or n type. In some embodiments, the substrate 11 is a silicon substrate that is doped with p type or n type dopants. Dopant concentration of a bulk of the substrate 11 may be at a level of about 1e15/cm³ to about 1e17/cm³, and additional doping regions of dopant concentration that exceeds the bulk may be embedded in the bulk of the substrate 11. Description of the substrate 11 is provided in greater detail with reference to FIG. 5.

As depicted in FIG. 1A, the SPADs 100 may be arranged in a plurality of rows and a plurality of columns that form an array. The SPADs 100 may have uniform dimensions in a first direction (e.g., an X-axis direction) and a second direction (e.g., a Y-axis direction). For example, widths of the SPADs 100 may be uniform across the array and lengths of the SPADs 100 may be uniform across the array. In some embodiments, widths and/or lengths of the SPADs 100 may be in a range of about 5 micrometers (um) to about 30 um. Distances between SPADs 100 may be uniform across the array. For example, spacing and/or pitch of the SPADs 100 in each column may be uniform in the Y-axis direction, and spacing and/or pitch of the SPADs 100 in each row may be uniform in the X-axis direction. The SPADs 100 of the array may be associated with a pixel binning and/or one or more algorithms.

In FIG. 1B, SPADs 100A, 100B, 100C, 100D, 100E of varying dimensions may be arranged on the substrate 11 instead of the SPADs 100 having uniform dimensions. The SPADs 100A, 100B, 100C, 100D, 100E may be referred to collectively as the SPADs 100A-100E. Five SPADs 100A-100E of different dimensions are depicted in FIG. 1B, but fewer or additional SPADs may be included in some embodiments. The SPADs 100E may have dimension(s) that exceed those of the SPADs 100D, which may have dimension(s) that exceed those of the SPADs 100C, which may have dimension(s) that exceed those of the SPADs 100B, which may have dimension(s) that exceed those of the SPADs 100A. The SPADs 100E may be arranged to the right of the SPADs 100D, which may be arranged to the right of the SPADs 100C, which may be arranged to the right of the SPADs 100B, which may be arranged to the right of the SPADs 100A. In some embodiments, the SPADs 100A-100E may be arranged to have increasing dimension(s) (e.g., width and/or length) from left to right or from right to left. In some embodiments, dimension(s) of the SPADs 100A-100E may increase from a center of the substrate 11 (or sensing region of the substrate 11) to a periphery of the substrate 11 (or the sensing region) along one or more of the direction X and the direction Y, an example of which is depicted in FIG. 1C for variation along the direction X. FIG. 1C depicts an image sensor 10B that includes SPADs 100A-100E having dimensions that gradually decrease along the X-axis direction from a center of the image sensor 10B to a periphery of the image sensor 10B.

In some embodiments, the SPADs 100 or 100A-100E may be arranged differently than depicted in FIGS. 1A-1C. For example, SPADs having different dimensions (e.g., different widths, lengths, pitches, spacings or a combination thereof) may be arranged in a uniform or non-uniform, periodic or aperiodic manner across the image sensor 10 (or 10A or 10B) along the X axis, the Y axis or both. For example, a pair of rows of SPADs may have a first row including first SPADs having uniform first width and first length and a second row including second SPADs having uniform second width and second length that are different than the first width and first length. An array may include two or more of the pairs of rows just described. In another example, the first or second row or both may include SPADs having non-uniform widths and lengths along the respective row. In another example, instead of a pair of rows, an array of triplets, quadruplets or larger groups of rows may be arranged in which first, second, third, fourth or additional rows each have SPADs of uniform or non-uniform dimensions in the respective row.

Each SPAD 100, 100A-100E may be included in a pixel of the image sensor 10, 10A, 10B, respectively. In operation, such as during image capture for inspecting an EUV photomask, a single line of the SPADs 100 or 100A-100E may perform a capture function while other lines of the SPADs 100 or 100A-100E may be used for calibration, gain feedback, or both. For example, a single row of the SPADs 100 that extends along the X-axis direction may be utilized for capturing image data associated with the EUV photomask, while other row(s) of the SPADs 100 may be utilized for calibrating the single row. In some embodiments, two or more of the rows of the SPADs 100 or 100A-100E may be utilized for capturing the image data.

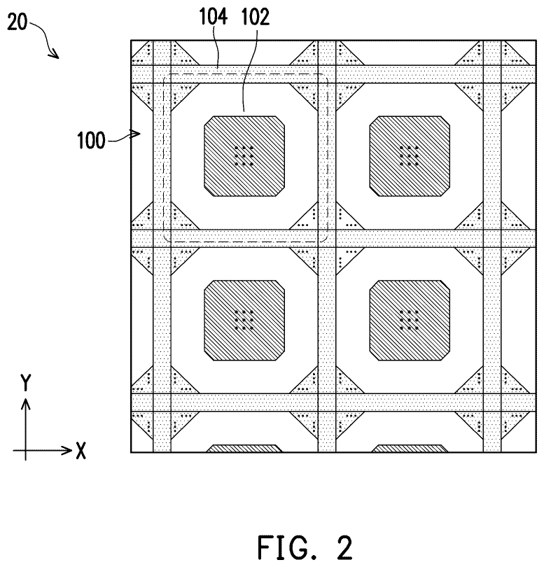

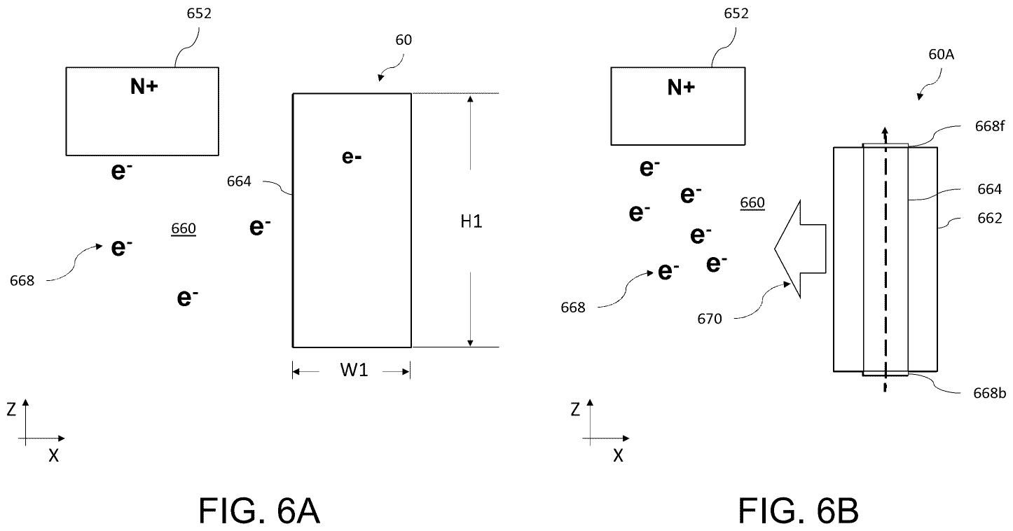

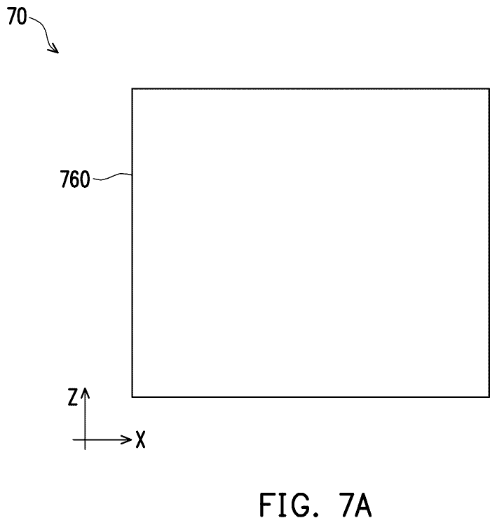

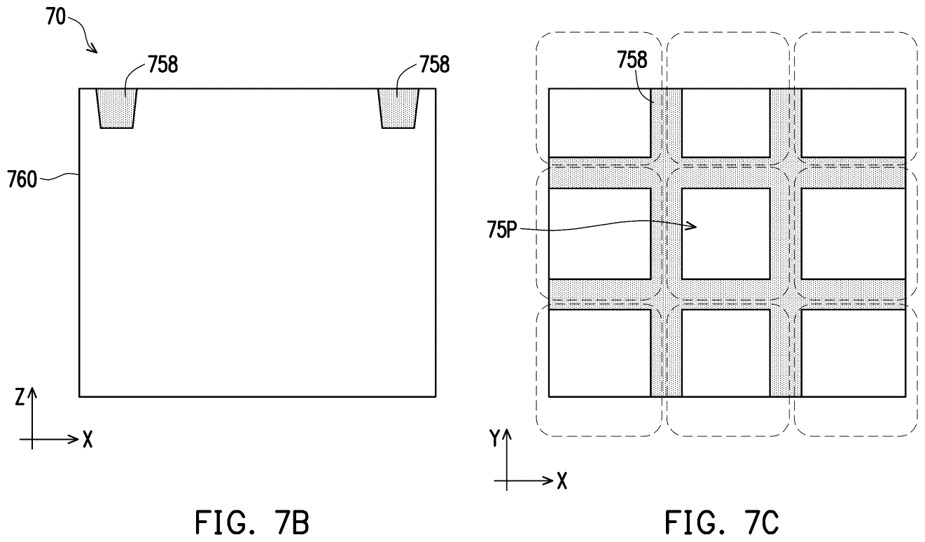

FIG. 2 depicts a detailed view of a region 20 of the image sensor 10 depicted in FIG. 1A. In the region 20, at least four SPADs 100 are included, each having a first doped region 102 and a second doped region 104 that is adjacent to and offset from the first doped region 102 along at least four sides thereof. In some embodiments, the first doped region 102 is an n type doped region having dopant concentration that exceeds about 1e16/cm³ and the second doped region 104 is a p doped region having dopant concentration that exceeds about 1e16/cm³. In some embodiments, as depicted in FIG. 2, the first doped regions 102 are substantially square regions that may have chamfered corners. Although not specifically illustrated in FIG. 2 for simplicity, each of the SPADs 100 may be isolated from neighboring SPADs 100 by one or more isolation structures, which will be described in greater detail with reference to FIGS. 5 and 6.

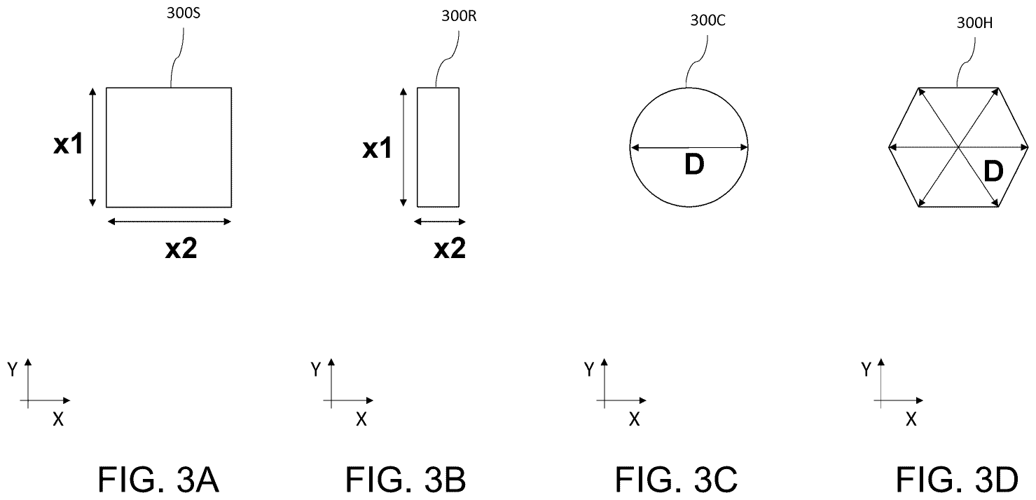

FIGS. 3A-3D are diagrammatic views of SPADs 300S, 300R, 300C, 300H having different shapes in accordance with various embodiments. The SPADs 300S, 300R, 300C, 300H can be embodiments of the SPADs 100 or the SPADs 100A-100E described with reference to FIGS. 1A-2. FIG. 3A depicts a SPAD 300S that has square shape, in which a width x2 thereof is equal to a length x1 thereof. FIG. 3B depicts a SPAD 300R that has rectangular shape, in which the length x1 thereof exceeds the width x2 thereof. For example, the width x2 may be less than about ¾ of the length x1. FIG. 3C depicts a SPAD 300C that has circular shape having diameter D. FIG. 3D depicts a SPAD 300H having polygonal shape, such as hexagonal shape having maximal/maximum diameter D. The width x2, the length x1, the diameter D and the maximum diameter D just described may each be in a range of about 5 um to about 30 um. In some embodiments, the SPADs 100 or the SPADs 100A-100E have shapes other than those depicted in FIGS. 3A-3D. For example, the polygonal shape of the SPAD 300H may be pentagonal, octagonal or the like. In some embodiments, the shape of the SPAD 100 or the SPAD 100A-100E can refer to shape of the first doped region 102. Namely, instead of the square-shaped first doped region 102 depicted in FIG. 2, the first doped region 102 may have the rectangular shape, the circular shape, the polygonal shape, or other similar such shape. In some embodiments, one or more of the SPADs 100 or the SPADs 100A-100E may have a shape (e.g., circular) that is different from that of one or more other(s) of the SPADs 100, 100A-100E (e.g., square). The circular shape may be beneficial for the image sensors 10, 10A, 10B when included in microscopy devices, astronomical devices, and the like. The hexagonal shape may be beneficial for the image sensors 10, 10A, 10B to have a more compact sensor layout with increased pixel density.

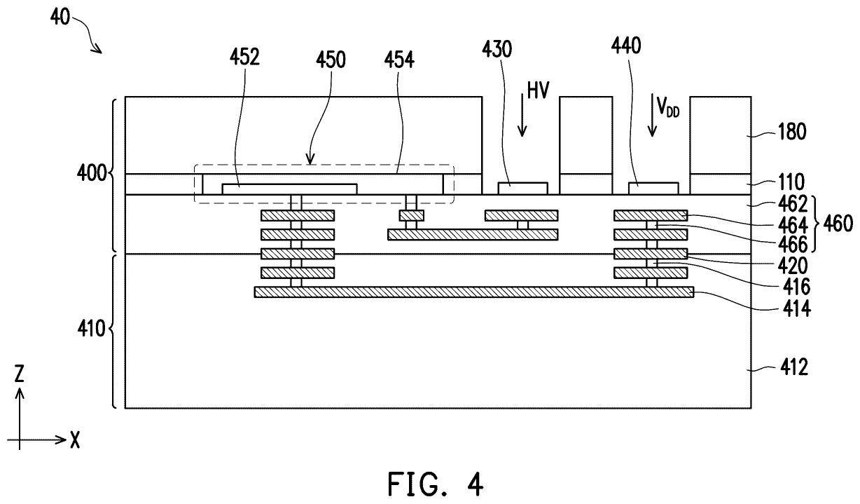

FIG. 4 is a diagrammatic view of a portion of an image sensor device 40 in accordance with various embodiments. FIG. 4 depicts the portion of the image sensor device 40 in an X-Z plane. The image sensor device 40 may include an image sensor 400 that is stacked with an integrated circuit (IC) 410. The image sensor device 40 includes one or more SPADs 450, which may be similar in most respects to the SPADs 100, 100A-100E, 300S, 300R, 300C, 300H described with reference to FIGS. 1A-3D. The integrated circuit 410 may be or include an application-specific integrated circuit (ASIC), which may include logic circuitry, such as processor circuitry, memory circuitry, data interface (I/O) circuitry and the like.

In FIG. 4, the SPAD-based image sensor 400 may be operable to perform a first group of functions and the ASIC 410 may be operable to perform a second, different group of functions. For example, the image sensor 400 may, in operation, detect photons and perform avalanche multiplication, temporal resolution and pixel-level processing. Photon detection may be a function of the SPAD-based image sensor 400 and includes detecting single photons. Each SPAD 450 of the image sensor 400 can act as a highly sensitive photodetector, capable of generating a detectable signal from absorption of a single photon. Upon detecting a photon, the detecting SPAD 450 initiates an avalanche multiplication process, amplifying the initial signal to a detectable level. SPAD sensors 400 can offer improved timing resolution, making them suitable for applications that benefit from precise timing of photon arrival, such as time-of-flight (ToF) measurements and fluorescence lifetime imaging. The SPAD sensor 400 may integrate basic processing functions at the pixel level, such as time gating or photon counting, to improve efficiency of photon detection and signal processing.

The ASIC 410 can handle complex signal processing, including noise reduction, signal amplification and data conversion from analog to digital format, each of which may be performed by associated circuitry, such as noise reduction circuitry, signal amplification circuitry, data conversion circuitry (e.g., analog-to-digital convertor circuitry) and the like. This processing is beneficial for preparing the raw data captured by the SPAD sensor 400 for further analysis. The ASIC 410 can manage data flow, including storage, buffering and transmission of image data generated by the image sensor 400. This can include organizing the data from multiple SPAD pixels 450, compressing the data if beneficial, and preparing the data for output. The ASIC 410 can control timing and synchronization of operations of the image sensor 400, including pulse generation for active illumination (if used) and synchronization with external devices. This is beneficial for applications like 3D imaging and range finding, where precise timing between emission and detection improves performance. Efficient power management can be beneficial for portable or battery-operated devices. The ASIC 410 improves power consumption efficiency by regulating a power supply to the SPAD sensor 400 and by implementing power-saving modes. The ASIC 410 can provide interfaces for communication with external devices, such as computers, displays, or other sensors. This includes implementing protocols for data transfer and receiving commands from an external processor or controller.

In some embodiments, although not specifically depicted in FIG. 4 for simplicity of illustration, the ASIC 410 may include one or more integrated devices, such as metal-oxide-semiconductor (MOS) transistors, capacitors, resistors, inductors, diodes, memory devices, combinations thereof and the like. The MOS transistor(s) may include field-effect transistor(s) (FET(s)), which may be planar FET(s), fin-type FET(s), nanostructure FET(s), combinations thereof and the like. The nanostructure FET(s) can include a nanosheet FET (NSFET), nanowire FET (NWFET), gate-all-around FET (GAAFET) and the like.

The image sensor 400 may include a substrate 110 having SPADs 450 therein and one or more pads 430, 440 thereon or therein. A backside passivation layer 180 may be positioned on a back side of the substrate 110. A frontside interconnect structure 460 may be positioned on a front side of the substrate 110.

The frontside interconnect structure 460 may include metallization structures 464, 466 embedded in one or more dielectric layers 462. The metallization structures 464, 466 can include conductive traces 464 and conductive vias 466. The metallization structures 464, 466 can be electrically coupled to the pads 430, 440 and the SPADs 450 to provide electrical connectivity therebetween.

For example, a first pad 430 may be coupled to the SPAD 450 via metallization structures 464, 466 that are only positioned in the dielectric layers 462 of the frontside interconnect structure 460. The first pad 430 may receive a high voltage HV from a first power supply that is external to the image sensor 400. In some embodiments, the high voltage HV, in operation, may be transmitted to a second doped region 454 of the SPAD 450 via the frontside interconnect structure 460, as depicted in FIG. 4.

A second pad 440 may be coupled to the SPAD 450 via the metallization structures 464, 466 of the frontside interconnect structure 460 and additional metallization structures 414, 416 that are included in the ASIC 410. The second pad 440 may receive a supply voltage V_{DD} from a second power supply that is external to the image sensor 400. In some embodiments, the supply voltage V_{DD}, in operation, may be transmitted to a first doped region 452 of the SPAD 450 via the frontside interconnect structure 460 and interconnects within the ASIC 410.

In some embodiments, the image sensor 400 and the ASIC 410 are bonded to each other. For example, the image sensor 400 and the ASIC 410 may be bonded to each other via a hybrid bond that includes at least one metal bond 420 between a metallization structure of the image sensor 400 and a metallization structure of the ASIC 410. Additional bonding (e.g., a dielectric bond) may be present between respective dielectric layer(s) of the image sensor 400 and the ASIC 410 adjacent the metal bond(s) 420.

The passivation layer 180 may be positioned on the back side surface of the substrate 110 including the SPAD 450. In some embodiments, the passivation layer 180 may include SiN, SiC, SiON, SiO2, SiCN, polymers or the like, which may be selected for protective, optical and electrical properties. For example, the passivation layer 180 may be an insulating layer that prevents leakage current and oxidation of underlying layers, such as the substrate 110. In some embodiments, the passivation layer 180 may be a single layer that is epitaxially grown and provides a capping function. The passivation layer 180 may have thickness that exceeds about 10 nm or is less than about 5 nm. For example, when radiance of an EUV light source is in a range of about 50 W/mm²Sr to about 200 W/mm²Sr, the thickness of the passivation layer 180 may exceed about 10 nm. When the radiance of the EUV light source is less than about 50 W/mm²Sr, the thickness of the passivation layer 180 may be less than 5 nm.

The passivation layer 180 may provide several beneficial functions aimed at enhancing performance, longevity and reliability of the image sensor 400. The passivation layer 180 can provide a protective barrier against environmental factors such as moisture, oxygen, and contaminants that could potentially damage the image sensor 400. This protection is beneficial for maintaining integrity of sensitive areas of the SPADs 450 given that the back side surface may be exposed to the environment after a thinning process in fabrication of the BSI sensor 400. The backside surface of the silicon wafer or substrate 110 can introduce trap states that adversely affect the performance of the SPADs 450 by increasing dark counts or reducing quantum efficiency. The passivation layer 180 can help to mitigate these effects by smoothing the surface and reducing the number of surface defects and trap states. For BSI SPAD sensors, such as the image sensor 400, improving the passage of light to the active area is beneficial. The passivation layer 180 can be selected to improve optical properties of the back side surface, including enhancing reflectivity or reducing scattering, thus increasing number of photons that reach respective avalanche regions of the SPADs 450. This is particularly beneficial for improving sensitivity and efficiency. The passivation layer 180 can also play a role in electrical isolation, preventing leakage currents and ensuring that electrical characteristics of the SPADs 450 are preserved. This isolation is beneficial for maintaining performance of the image sensor 400 over time and under varying environmental conditions. During the fabrication process and in operational use, the image sensor 400 can be subjected to mechanical stresses that may affect performance thereof. The passivation layer 180 can help to manage these stresses, increasing mechanical stability of the device 40.

FIG. 5 is a diagrammatic view depicting a portion of an image sensor device 50 in accordance with various embodiments. The image sensor device 50 may be an embodiment of the image sensor device 40 described with reference to FIG. 4 and may be similar in most respects to the image sensor device 40.

The image sensor device 50 may include an image sensor structure 55, a system-on-a-chip (SOC) 500 and an ASIC 510. The ASIC 510 may be similar in most respects to the ASIC 410 and further description thereof is not provided again here. In some embodiments, the SOC 500 includes the image sensor structure 55 and pads 530, 540 thereon. The SOC 500 may include an interconnect structure similar to the frontside interconnect structure 460 described with reference to FIG. 4. In some embodiments, the SOC 500 includes one or more of the functions described with reference to the ASIC 410 of FIG. 4. For example, the SOC 500 may include one or more of the image sensor structure 55, the pads 530, 540, ADC(s), DSP(s), memory circuitry, control logic circuitry, interface circuitry, power management (unit) (PMU) circuitry and the like, and the ASIC 510 may include one or more of advance image processing circuitry, additional interface circuitry, control logic (e.g., for focusing a lens assembly), security circuitry, and the like. The pads 530, 540 may be similar in most respects to the pads 430, 440, respectively.

The image sensor structure 55 includes features that are beneficial to improve resolution, reduce gain noise and circuit noise and have increased efficiency.

The image sensor structure 55 may include one or more SPADs 550, a multilayer reflector or “reflective multilayer” 570 and a passivation or capping layer 572. The multilayer reflector 570 may be, for example, a structure that is coated onto a front side 550f of the SPAD 550. The capping layer 572 may be similar in most respects to the passivation layer 180 described with reference to FIG. 4 and may be an epitaxially grown layer positioned on a back side 550b of the SPAD 550.

The SPAD 550 may be similar in most respects to the SPAD 450 described with reference to FIG. 4. The SPAD 550 is depicted and described in greater detail with reference to FIG. 5.

In FIG. 5, the SPAD 550 may include a sensing node 552 in a substrate 560. The SPAD 550 may further include common nodes 554, a guard ring 556, isolation structures 558 and isolation extension structures 5600.

The sensing node 552 may be a region of the substrate 560 that is heavily doped with dopants of a first conductivity type, e.g., n type, as indicated by a marker “N+” in FIG. 5. The sensing node 552 may be formed in the substrate 560 and may extend downward (e.g., inward) from the front side 550f of the SPAD 550. In some embodiments, dopant concentration of the sensing node 552 is at a level that exceeds about 1e18/cm³, such as about 1e20/cm³.

In the fabrication of BSI SPADs, such as the SPAD 550, n-type dopants are introduced in the sensing node 552 to facilitate the electron-initiated avalanche multiplication process. Selection of the n-type dopant can depend on a semiconductor material, e.g., silicon, of the substrate 560 and selected electrical characteristics. The n-type dopants for silicon can include phosphorous, arsenic, antimony or the like. Phosphorus may be beneficial to easily donate electrons to the conduction band of silicon, creating free carriers (electrons) for conduction. Arsenic is another n-type dopant that can generate a high concentration of electrons in silicon and can be beneficial for fast diffusivity and creating highly doped n+ regions. Although less common than phosphorus and arsenic, antimony can be used where slower diffusion is beneficial for the doping process. The doping process may be controlled to achieve beneficial concentration and depth profiles for operation of the SPAD 550. The n-type doping is beneficial for forming a multiplication region 566 where the avalanche breakdown occurs in response to incident photons.

The common node 554 is formed in the substrate 560 and may extend downward (e.g., inward) from the front side 550f of the SPAD 550. In some embodiments, the common node 554 may be a region of the substrate 560 that is heavily doped with dopants of a second conductivity type, e.g., p type, that is different from or opposite to the first conductivity type. The common node 554 may be labeled with “P+” in FIG. 5 to indicate that it is a heavily doped p-type region. In some embodiments, dopant concentration of the common node 554 is at a level that exceeds about 1e18/cm³, such as about 1e20/cm³.

As shown in FIG. 5, the sensing node 552 and the common node 554 are positioned adjacent to the front side 550f of the SPAD 550. The multiplication region 566 (or “avalanche zone”) is positioned below the sensing node 552 in the Z-axis direction as shown in FIG. 5. The guard ring 556 may extend downward further from the front side 550f of the SPAD 550 than the multiplication region 566. The guard ring 556 may have a width sufficient to prevent premature breakdown and to ensure uniform electric field distribution. In at least some implementations, the sensing node 552 may have a width (in the X-axis direction) that is between 0.1 um and 10.0 um inclusive, and may have a height (in the Z-axis direction) that is less than or equal to 0.5 um. The common node 554 may have a width that is between 0.1 um and 1.0 um, inclusive, and may have a height that is less than or equal to 0.5 um. The guard ring 556 may have a width that is between 0.1 um and 5.0 um inclusive, and may have a height that is between 0.5 um and 1.5 um inclusive. The multiplication region 566 may have a width that is between 0.5 um and 10.0 um inclusive, and may have a height that between 0.1 um and 1.0 um inclusive.

Biasing the BSI SPAD 550 for photon detection can involve applying a reverse voltage across a p-n junction of a diode to initiate and sustain an avalanche multiplication process upon the detection of a photon. The SPAD 550 can be reverse-biased, meaning that a positive voltage (e.g., V_{DD} at the pad 540) is applied to the n-type region (e.g., the sensing node 552) and a negative voltage (e.g., HV at the pad 530) to the p-type region (e.g., the common node 554), creating an electric field across the junction. This bias is set to a voltage level above the breakdown voltage of the diode, a state referred to as “Geiger mode.” The breakdown voltage can be a minimum reverse voltage at which the diode's junction is able to conduct a substantial reverse current without the presence of light. For photon detection, the bias voltage is set slightly above this threshold, a condition called “over-biasing,” which puts the diode in a metastable state ready to undergo avalanche multiplication with the arrival of a photon. Due to the bias of the SPAD 550 being above the breakdown voltage, gain of the SPAD 550 may be very high via impact ionization, such that a single photon can trigger an avalanche current that quickly exceeds about 10 microampere or more.

When a photon enters the SPAD through the back side 550b, if the photon has sufficient energy, it can generate an electron-hole pair shown by electrons 568 in the substrate region 560 of the SPAD 550. The generated charge carriers (e.g., electron-hole pair) are accelerated by the electric field toward the sensor node 552. If the electric field is strong enough (due to the over-biasing), these carriers gain enough kinetic energy to ionize other atoms in an avalanche region 566 through impact ionization, creating more carriers. This process cascades, leading to a rapid multiplication or “avalanche” of charge carriers. The avalanche results in a sharp current pulse, which can be detected as a signal that a photon has been absorbed. The avalanche region 566 can be a region that is bordered by or immediately adjacent to the sensor node 552 and the guard ring 556, as depicted in FIG. 5. The avalanche region 566 may extend outward from the sensor node 552 and may not extend beyond the guard ring 556 in a vertical direction (e.g., the Z-axis direction of FIG. 5). The avalanche region 566 may be a region that has formation associated with position of the sensor node 552 and thickness of the substrate 560. For example, the avalanche region 566 may not form when thickness of silicon of the substrate 560 exceeds about 5 micrometers.

Once the avalanche has been triggered, the current is quickly quenched to prevent thermal damage to the SPAD 550 and to reset the diode 550 for detecting the next photon. Quenching can be achieved by reducing the bias voltage below the breakdown voltage, either passively (using a resistor) or actively (using electronic circuits). After quenching, the voltage is restored to its initial level above the breakdown voltage, re-establishing the Geiger mode condition and preparing the SPAD for the next photon detection event. The biasing and subsequent operation of a BSI SPAD benefit from careful control of the applied voltage(s) and timing of the quenching and resetting processes to ensure sensitive, accurate, and repeatable photon detection.

The multilayer reflector 570 may be positioned between the front side 550f of the SPAD 550 and the SOC 500. In some embodiments, the multilayer reflector 570 may include a number of pairs of layers or “bilayers” that are coated onto the front side 550f of the SPAD 550. In some embodiments, the multilayer reflector 570 may include trilayers, four-layer structures, or the like. The bilayers may be or include individual layers of molybdenum and silicon. In some embodiments, the bilayers, trilayers, four-layer structures or otherwise can include additional materials having high extinction coefficient, such as ruthenium, strontium, niobium, beryllium, or the like. In one example, a bilayer may include a first layer that includes molybdenum having thickness of about 3.5 nm and a second layer that includes silicon having thickness of about 3.5 nm, and number of the bilayers in the multilayer reflector 570 may be in a range of about 5 bilayers to about 40 bilayers. Inclusion of the multilayer reflector 570 can enhance intensity of EUV light to improve detection of photons by the SPAD 550. In some embodiments, the multilayer reflector 570 includes one or more additional layers, such as a protective capping layer that can protect the bilayers of the multilayer reflector 570 from moisture or other similar environmental factors that can damage the bilayers. One or more buffer or dielectric layers may be present between the multilayer reflector 570 and the front side 550f of the SPAD 550.

The guard ring 556 is positioned between the sensing node 552 and the common node 554. The guard ring 556 in the BSI SPAD 550 can be included to improve prevention of premature edge breakdown and to isolate the sensing node 552 from other structures, such as the common node 554. The guard ring 556 may include the same semiconductor material as the substrate 560 of the SPAD 550, e.g., silicon. The guard ring 556 can be doped with the same type of dopants as the sensing node 552 of the SPAD 550 but at different concentrations. For example, the guard ring 556 may be doped to form a p-n junction around the active area of the SPAD 550. For instance, in an n-type SPAD 550, the guard ring 556 can be p-doped to create a p-n junction. In some embodiments, multiple rings 556 with varying doping levels can be included to create a more gradual electric field gradient. For example, the guard ring 556 may have multiple concentric rings or a single ring with a width selected to beneficially control the electric field effectively. The guard ring 556 may be positioned surrounding the sensing node 552 and separated therefrom by a selected distance to ensure that the electric field does not trigger an unintended avalanche breakdown at edges of the sensing node 552. In some embodiments, a passivation layer (not depicted for simplicity of illustration), such as silicon dioxide (SiO₂) or silicon nitride (Si₃N₄), can be applied over the guard ring 556. This passivation layer is beneficial to protect the underlying semiconductor and electrically isolate the guard ring. The guard ring 556 is beneficial for performance of the SPAD 550, as the guard ring 556 can help to reduce dark count rates and increase photon detection probability by ensuring that the sensing node 552 operates within the intended voltage range without interference from edge effects.

The SPAD 550 may be isolated physically, optically and electrically from neighboring SPADs via isolation structures 558 and isolation extension structures 5600. In some embodiments, the isolation structures 558 are shallow trench isolation (STI) structures. The isolation structures 558 may abut or be immediately adjacent to the common node 554. In some embodiments, although two isolation structures 558 are depicted in FIG. 5, the isolation structures 558 may be portions of a single, continuous isolation structure 558 that surrounds the common node 554, the guard ring 556 and the sensor node 552. The isolation structure(s) 558 may be or include a dielectric material, such as an oxide (e.g., silicon oxide), a nitride (e.g., silicon nitride or silicon oxynitride), a low-k dielectric, another suitable dielectric, combinations thereof and the like.

The isolation extension structure(s) 5600 may include a metal or conductive layer 564 and a side surface isolation layer 562 on the conductive layer 564. The conductive layer 564 may be beneficial to prevent emission distribution between neighboring SPADs due to recombination of electrons and holes. In some embodiments, the conductive layer 564 can serves as conduction path for electrons and holes. The conductive layer 564 can be or include one or more of W, Ta, Cu and the like. Width of the conductive layer 564 in the horizontal direction (e.g., the X-axis direction) can be less than about 0.3 micrometers (um). Height of the conductive layer 564 in the vertical direction (e.g., the Z-axis direction) can be less than about 2.5 um. The side surface isolation layer 562 can be an oxide layer (e.g., silicon oxide), a nitride layer (e.g., silicon nitride or silicon oxynitride), a low-k dielectric layer, another suitable dielectric layer, combinations thereof and the like. The side surface isolation layer 562 is beneficial to prevent photoelectron leakage to nearby SPADs. Width of the side surface isolation layer 562 may be less than about 0.1 um. Height of the side surface isolation layer 562 may be less than about 2.5 um. Material of the side surface isolation layer 562 may be different than that of the isolation structure 558. An upper surface of the side surface isolation layer 562 may be in direct contact with a lower surface of the isolation structure 558. In at least some embodiments, the surface isolation layer 562 may extend along the X-axis direction to overlap (in the Z-axis direction) with at least a portion of the common node 554. One side surface of the side surface isolation layer 562 may be in direct contact with the substrate 560 and another side surface of the side surface isolation layer 562 may be in direct contact with the conductive layer 564. Height of the side surface isolation layer 562 may be the same as or substantially the same as height of the conductive layer 564.

The combination of the isolation structure(s) 558 and the isolation extension structure(s) 5600 can extend vertically from the front side 550f of the substrate 560 to the back side 550b of the substrate 560. For example, the isolation structure(s) 558 can extend from the front side 550f to a first level that is near a lower surface of the common node 554 or that is between the lower surface of the common node 554 and a lower surface of the guard ring 556. The isolation extension structure(s) 5600 can extend from the first level to the back side 550b. As shown in FIG. 5 the isolation structure(s) 558 may have smaller width at its bottom and a larger width at its top, with the width gradually increasing (e.g., linearly) from the bottom to the top of the isolation structure(s). In at least some embodiments, the isolation extension structure(s) 5600 may have a width that is uniform from its top to its bottom.

FIGS. 6A and 6B are views of isolation extension structures 60, 60A that may be embodiments of the isolation extension structure 5600. The isolation extension structures 60, 60A can prevent emission distribution between neighboring devices by recombination of electrons and holes. The isolation extension structures 60, 60A can serve as a conduction pathway for electrons and holes. In FIG. 6A, the isolation extension structure 60 is or includes a conductive layer 664, which may be or include a metal layer formed of W, Ta, Cu, combinations thereof or the like. The isolation extension structure 60 may have width W1 in the X-axis direction that is less than about 0.3 micrometers. The isolation extension structure 60 may have height H1 in the Z-axis direction that is less than about 2.5 micrometers. The height H1 being less than about 2.5 micrometers is beneficial for the substrate 560 to be thinner than about 5 micrometers, which aids in forming the avalanche region 566. In some embodiments, the isolation extension structure 60 does not include the side surface isolation layer. Namely, the metal layer of the isolation extension structure 60 may be in direct contact with the substrate 560.

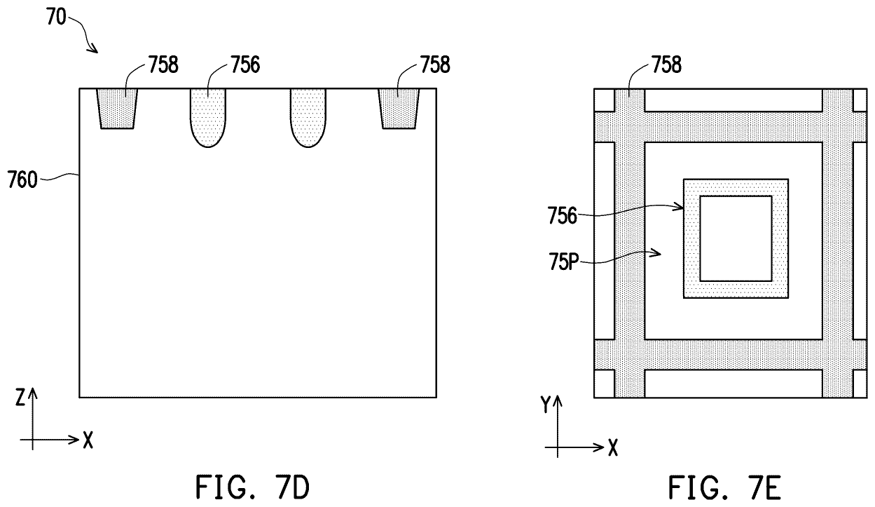

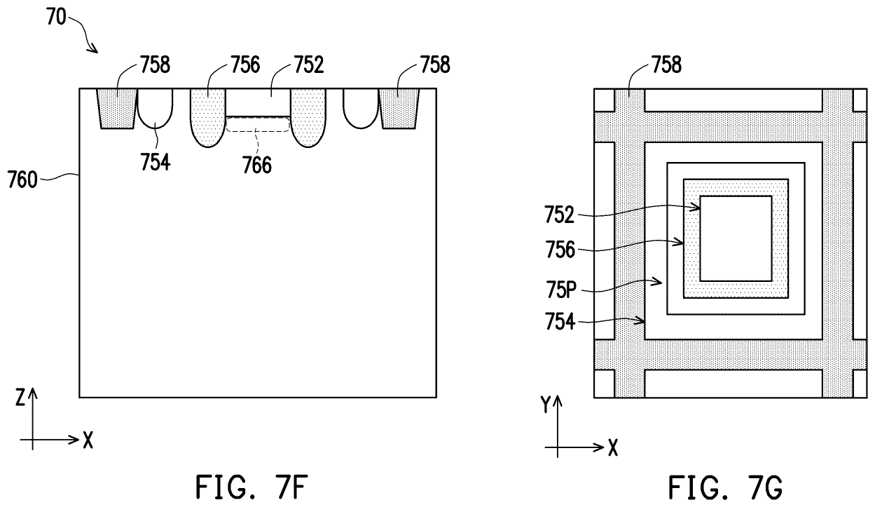

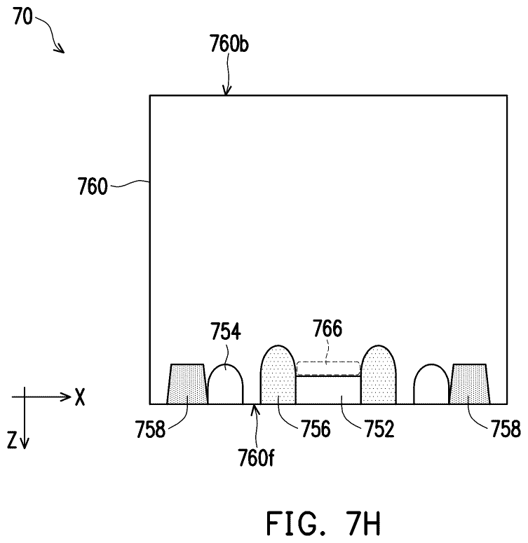

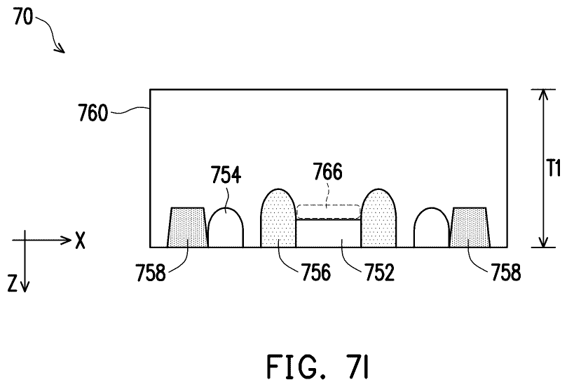

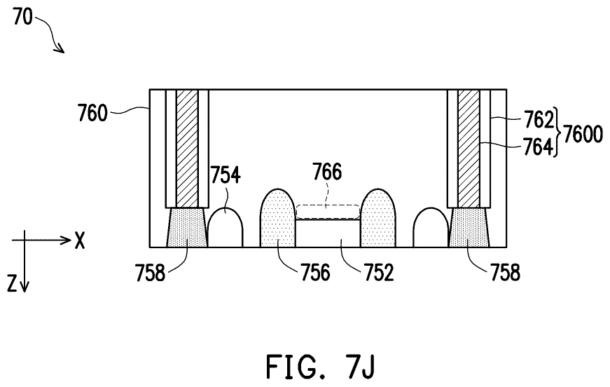

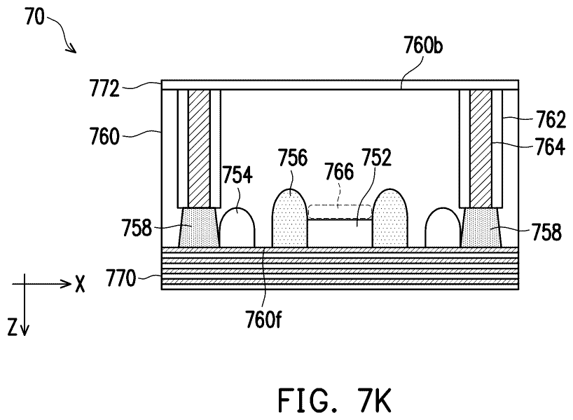

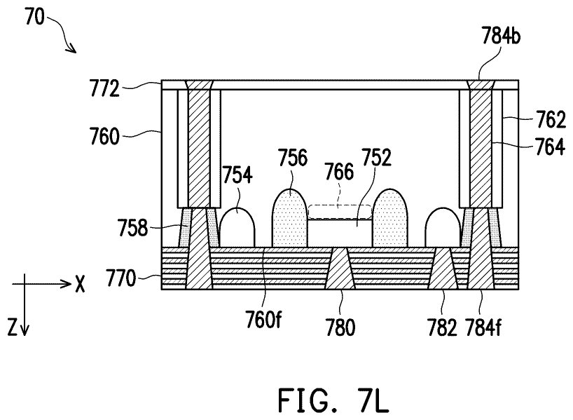

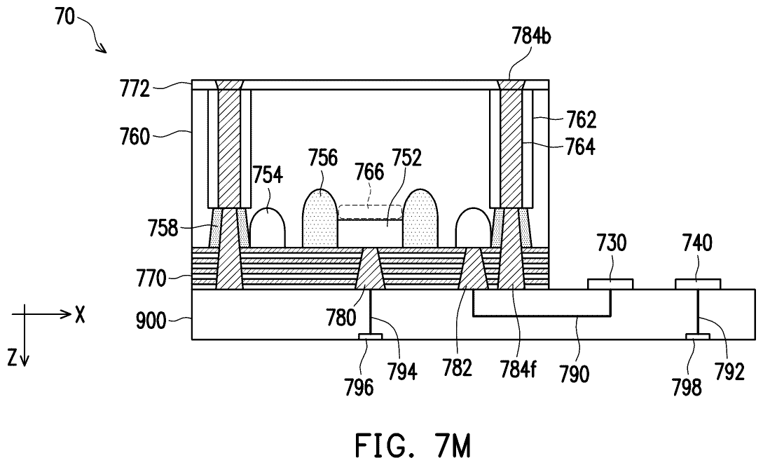

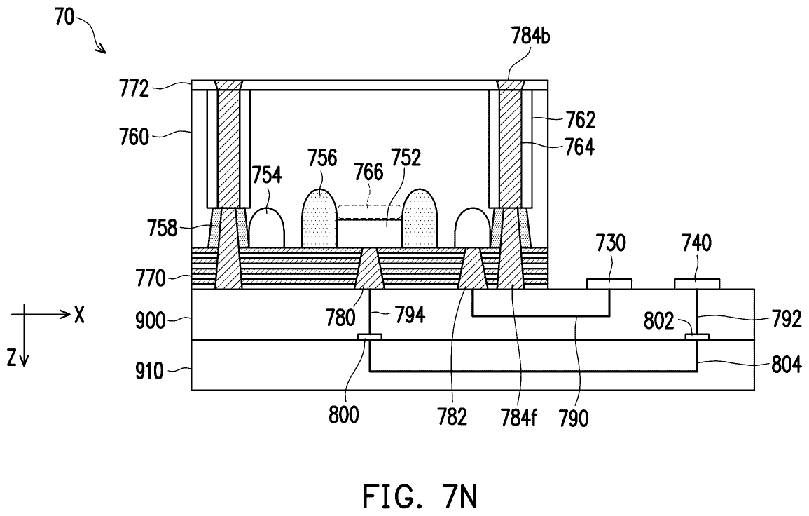

In some embodiments, as depicted in FIG. 6B, the isolation extension structure 60A may include a side surface isolation layers 662 between the conductive layer 664 and the substrate (e.g., the substrate 560). The side surface isolation layers 662 may be dielectric layers, such as SiO, SiC, SiN, SiOC, SiON, SiCN, SiOCN or the like. The side surface isolation layers 662 may isolate the conductive layer 664 electrically from the substrate (e.g., the substrate 560). Because the conductive layer 664 is electrically isolated from the substrate, a bias voltage may be applied to the conductive layer 664, which is beneficial to generate an electrical field depicted by an arrow 670 in FIG. 6B. The electrical field can improve flow of electrons 668 toward the sensor node 552 and the avalanche zone 566, as depicted in FIG. 6B in comparison to FIG. 6A, in which the electrons 668 are more uniformly distributed across the substrate and even in the conductive layer 664. The bias voltage may be applied via front side electrode 668f and back side electrode 668b that are in contact with the conductive layer 664. As will be described in greater detail with reference to FIGS. 7L, the conductive layer 664 may be electrically connected to a bias voltage supply via contacts that extend through the multilayer reflector 570 and the passivation layer 572.

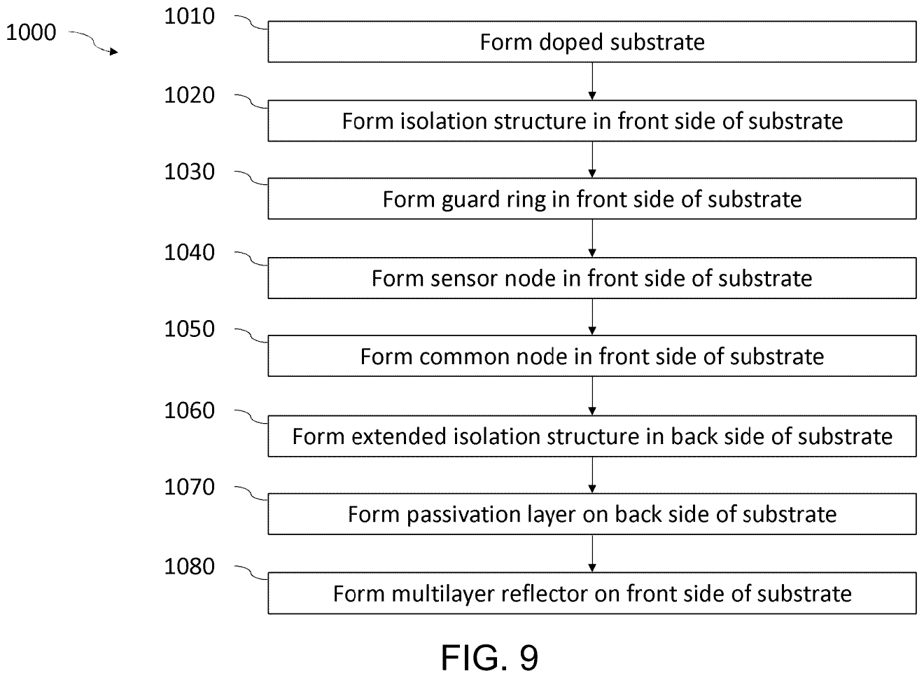

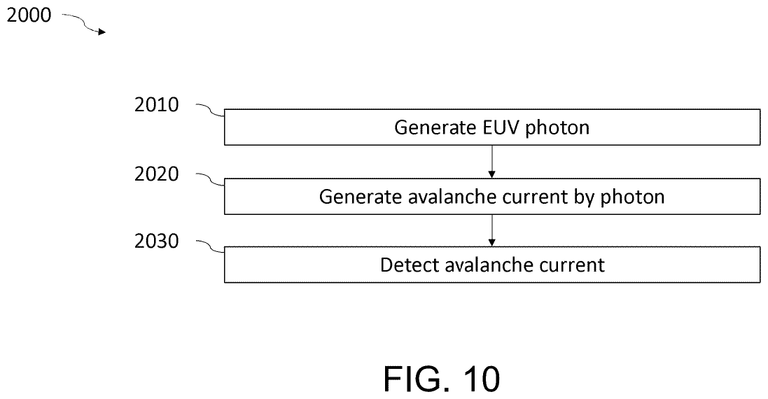

FIGS. 9 and 10 depict flowcharts of methods 1000, 2000 for forming an IC device (method 1000) or a portion thereof from a workpiece and detecting a photon by an IC device (method 2000), according to one or more aspects of the present disclosure. Methods 1000, 2000 are merely examples and not intended to limit the present disclosure to what is explicitly illustrated in methods 1000, 2000. Additional acts can be provided before, during and after the methods 1000, 2000 and some acts described can be replaced, eliminated, or moved around for additional embodiments of the method. Not all acts are described herein in detail for reasons of simplicity. Method 1000 is described below in conjunction with fragmentary perspective and/or cross-sectional views of an image sensor 70 or workpiece, shown in FIGS. 7A-7N, at different stages of fabrication according to embodiments of method 1000. Method 2000 is described in conjunction with a diagrammatic view of a system 80 for detecting or monitoring EUV photons. For avoidance of doubt, throughout the figures, the X direction is perpendicular to the Y direction and the Z direction is perpendicular to both the X direction and the Y direction. It is noted that, because the workpiece may be fabricated into a semiconductor device, the workpiece may be referred to as the semiconductor device as the context requires.

In FIG. 7A, a substrate 760 of the image sensor 70 is provided. The substrate 760 may be similar in most respects to the substrates 110, 560 described with reference to FIGS. 4 and 5. The substrate 760 may be a semiconductor substrate, such as a bulk semiconductor, or the like, which may be doped (e.g., with a p-type or an n-type dopant) or undoped. The semiconductor material of the substrate 760 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as single-layer, multi-layered, or gradient substrates may be used. In some embodiments, the substrate 760 is doped via a low damage implantation process, corresponding to act 1010 of FIG. 9. The substrate 760 may be doped with p-type dopants to a doping concentration of about 1e16/cm³.

As one non-limiting example, the low damage implantation process for doping the silicon substrate 760 with p-type dopants, such as boron (B), gallium (Ga), or indium (In), can introduce the dopants into the silicon substrate 760 to alter its electrical properties with reduced crystallographic damage. This is beneficial for maintaining the integrity of the semiconductor's lattice structure, which in turn affects device performance. The low damage implantation process may include p-type dopants like boron (B), gallium (Ga), or indium (In) based on selected electrical characteristics and application. Boron may be selected as the p-type dopant for silicon due to its effective integration into the silicon lattice and suitable energy levels. A relatively low implantation energy may be used to reduce lattice damage. Low energy can result in dopants being introduced near the surface of the substrate 760 without causing deep lattice disruptions. The dose, or the amount of dopants implanted, is controlled to achieve the selected doping concentration without excessive damage. Prior to implantation, surface preparation may be performed to clean the silicon substrate to remove any contaminants or native oxides. This step is beneficial for reducing possibility of implantation through or into unwanted materials that could affect the dopant distribution or cause additional damage. The implantation may be performed at reduced temperatures, such as around or even below room temperature. Cooling the substrate 760 during implantation can reduce defect formation by suppressing dynamic annealing processes that can otherwise repair some of the damage during implantation, thus keeping the process controlled and reducing unwanted diffusion of dopants. The dopants may be introduced at a slight angle rather than perpendicularly to the surface of the substrate 760. This technique can be beneficial in reducing channeling effects, where dopants penetrate deeply along crystallographic planes, leading to uneven doping profiles and excessive damage. Use of dopant clusters or molecular ions may be included in the implantation, which can reduce damage by spreading impact of the implantation over a larger area of the silicon lattice, decreasing concentration of energy transfer into the silicon atoms and thus reducing damage. After implantation, a thermal annealing process can be performed at a selected temperature. This step heals lattice damage by allowing the silicon atoms to move back into their correct positions, activating the dopants (i.e., allowing them to occupy substitutional sites in the silicon lattice), and restoring the crystalline structure. Ultra-low thermal budget annealing techniques, such as spike or flash annealing, can be selected to activate the dopants while reducing diffusion.

In FIGS. 7B and 7C, an isolation structure 758 may be formed in the substrate 760, corresponding to act 1020 of FIG. 9. The isolation structure 758 may be similar in most respects to the isolation structure 558 described with reference to FIG. 5. The isolation structure 758 may be shallow trench isolation (STI) structures. Two isolation structures 758 are depicted in FIG. 7B, however, in some embodiments, the isolation structures 758 are portions of a single, continuous isolation structure 758 as depicted in the plan view of FIG. 7C. The isolation structure 758 as depicted in FIG. 7C includes intersecting horizontal and vertical lines along the X- and Y-axis directions, which form pixel areas 75P associated with individual SPADs, such as the SPAD 550.

An example process for forming the isolation structures can include several photolithography, etching, and chemical vapor deposition (CVD) processes, as described briefly in the following. The example process starts with a clean silicon substrate 760. The surface of the substrate 760 may be prepared with a thin layer of oxide or nitride to facilitate further processing steps. A thin layer of silicon dioxide (pad oxide) can be thermally grown on the substrate 760. The pad oxide layer can serves as a buffer to relieve stress between the silicon substrate and a subsequently formed silicon nitride (Si₃N₄) layer, which has different thermal expansion coefficients. A layer of silicon nitride is then deposited over the pad oxide layer using, for example, chemical vapor deposition (CVD). The silicon nitride layer can act as a hard mask during a trench etch process and protect areas of the silicon substrate 760 that should not be etched away. A photoresist may be applied to the surface of the silicon nitride layer, and photolithography may be used to expose the photoresist according to a pattern of the trenches. The photoresist is exposed to ultraviolet (UV) light through or reflected from a photomask, which transfers the pattern of the trenches onto the photoresist. The exposed or unexposed regions of the photoresist, depending on the type of photoresist used, are then developed to reveal the pattern. With the pattern transferred to the photoresist, the substrate undergoes an etching process, such as reactive ion etching (RIE), to remove silicon nitride, pad oxide, and silicon in the exposed areas, forming trenches in the silicon substrate 760. Depth of the trenches can be less than about 2.5 nm. After etching, remaining photoresist is stripped using a plasma ashing process or a chemical solvent, leaving behind the patterned silicon nitride and the trenches in the silicon substrate 760. Optionally, corners of the trenches can be rounded using a thermal oxidation process. This step can reduce electric field concentration at the corners, which can improve device reliability. A dielectric material of the isolation structures 758, such as silicon dioxide, is deposited in the trenches, which can be via a CVD process. The deposition process can be followed by a chemical mechanical polishing to remove excess dielectric material and planarize the surface, leaving the dielectric of the isolation structure(s) 758 flush with the silicon nitride layer. The silicon nitride and underlying pad oxide layers are then removed. The nitride layer can be stripped via hot phosphoric acid, while the pad oxide can be removed using hydrofluoric acid (HF), thereby exposing the planarized oxide-filled trenches and the surface of the silicon substrate 760. The STI process can form electrically isolated regions 75P in the silicon substrate 760, allowing for the fabrication of densely packed SPADs with reduced leakage and cross-talk.

In FIGS. 7D and 7E, a guard ring 756 is formed, corresponding to act 1030 of FIG. 9. The guard ring 756 may be similar in most respects to the guard ring 556 described with reference to FIG. 5. The guard ring 556 may have a hollow quadrilateral shape in profile, as depicted in the plan view of FIG. 7E. In some embodiments, the guard ring 556 has a different shape in profile than that depicted, such as a rhombus shape, a polygonal shape (e.g., a hexagonal shape), a circular shape, or other suitable shape. The guard ring 756 may extend to a depth (e.g., in the Z-axis direction) that exceeds a depth to which the isolation structure 758 extends.

An example process for forming the guard ring 756 is described briefly in the following. The guard ring 756 may prevent premature edge breakdown and improve uniformity of electric field distribution across the SPAD. Forming the guard ring 756 may begin with the clean, lightly doped p-type or n-type silicon substrate 760, depending on selected electrical characteristics of the SPAD. In some embodiments, an appropriate well is formed in the substrate 760 where the active area of the SPAD will be located. The well can be formed via ion implantation or diffusion processes, where donor atoms (e.g., phosphorus or arsenic for n-type doping or boron for p-type doping) are introduced into the substrate 760. Around a perimeter of the intended active area, the guard ring 756 can be formed by implanting or diffusing dopants that are the same type as the substrate but at a higher concentration. For a p-type substrate, a higher concentration of p-type dopants (e.g., boron) is introduced to form a p+ guard ring 756. The guard ring 756 can serve to control the electric field and prevent edge breakdown by smoothly grading potential from the high-field region within the active area to the lower-field region outside it.

FIGS. 7F and 7G depict formation of sensing and common nodes 752, 754 in accordance with various embodiments, corresponding to acts 1040 and 1050 of FIG. 9, respectively. The sensing node 752 may be similar in most respects to the sensing node 552 described with reference to FIG. 5. The common node 754 may be similar in most respects to the common node 554 described with reference to FIG. 5. In some embodiments, the sensing node 752 is a heavily-doped n-type implantation region that is formed within the guard ring 756 and the common node 754 is a heavily-doped p-type implantation region that is formed outside the guard ring 756. The sensing node 752 generally abuts the guard ring 756 directly on all lateral sides. The common node 754 may be immediately adjacent to the isolation structure 758 as depicted in FIGS. 7F and 7G, or may be separated slightly from the isolation structure 758.

Forming an N+ sensing node 752 may involve a series of semiconductor fabrication operations aimed at creating a highly doped n-type region within the substrate 760, which is beneficial for the detection of single photons. The N+ sensing node 752 acts as a primary site where photon-triggered avalanche multiplication occurs. A concise description of one example process for forming the N+ sensing node in the substrate 760 follows. The process can start with a clean silicon substrate 760, which is p-type to establish a p-n junction with the N+ sensing node 752. In some embodiments, an optional n-well or deep n-well may be formed in the p-type substrate 760 prior to forming the sensing node 752 to create a selected electric field profile or to isolate the sensing node 752 electrically from the substrate 760. This step can include ion implantation or diffusion of n-type dopants, such as phosphorus or arsenic. Then, the surface of the substrate 760 can be oxidized to grow a thin silicon dioxide (SiO₂) layer. Photolithography can be used to pattern a photoresist on the oxide layer, exposing areas where the N+ sensing node 752 will be formed. The exposed region(s) is subjected to ion implantation with high-energy n-type dopants, such as phosphorus or arsenic, to form the N+ sensing node 752. The doping concentration of the sensing node 752 may be significantly higher than that of the substrate 760 or optional well to increase conductivity and efficient charge collection area. Post-implantation, an annealing step may be performed to repair implantation-induced lattice damage and activate the dopants of the sensing node 752, allowing them to occupy substitutional lattice sites. This step is beneficial for restoring the crystalline structure of the silicon and improving electrical activation of the implanted dopants.

In the above example, the sensing node 752 is an N+ sensing node 752. In such embodiments, the guard ring 756 may generally be doped with a type that complements that of the sensing node 752 while effectively preventing edge breakdown. For an N+ sensing node 752, which includes a highly doped N-type region designed to detect photons, the doping type for the guard ring 756 can be P-type. This P-type guard ring 756 serves several beneficial purposes. The P-type guard ring 756 around the N+ sensing node 752 helps manage the electric field gradient at the edges of the N+ region of the N+ sensing node 752. Appropriate selection of doping concentration and profile of the P-type guard ring 756 can result in a more uniform electric field distribution, which is beneficial in preventing concentration of the electric field at the edges, which can lead to premature edge breakdown. The P-type guard ring 756 can acts as a barrier that confines the high electric field within the N+ sensing node 752. This confinement is beneficial for preventing the edge breakdown, as it increases the likelihood that avalanche breakdown occurs uniformly across the sensing area 766 and not at the edges (e.g., outside the guard ring 756), where it can lead to noise and reduced detection efficiency. The presence of the P-type guard ring 756 around the N+ sensing node 752 also allows for better control of the breakdown voltage across the SPAD. By selecting the doping concentration and depth of the P-type guard ring 756, the breakdown voltage can be tuned to select operational parameters of the SPAD. It should be noted that, in some embodiments, the sensing node 752 may be a P+ sensing node 752, in which embodiments the guard ring 756 may be an N-type guard ring 756.

Formation of the common node 754 may be similar in many respects to the formation of the sensing node 752. In some embodiments, the sensing node 752 is a heavily-doped N-type (or “N+”) sensing node 752 and the common node 754 is a heavily-doped P-type (or “P+”) common node 754. The P+ common node 754 can serve as an electrical contact for the SPAD, ensuring efficient charge collection and providing a path for avalanche current generated during photon detection. In some embodiments, the common node 754 extends to a depth into the substrate 760 that is the same or similar to that to which the isolation structure 758 extends and that is shallower than that of the guard ring 756. The sensing node 752 may extend to a shallower depth than those of the common node 754 and the guard ring 756, which can be beneficial to prevent edge breakdown outside of the avalanche region 766.

In one example process for forming the P+ common node 754, outside the p+ guard ring 756, in the p-type substrate 760, the substrate 760 may be doped with a high concentration of p-type dopants to create a heavily doped region that serves as the main electrical contact for the device. For example, a photolithographic mask can be utilized to expose an area of the substrate 760 associated with the P+ common node(s) 754. The mask protects areas that should not receive additional doping, isolating the regions for the P+ common node 754. With the mask in place, a high concentration of p-type dopants, such as boron, is implanted into the exposed common node area of the substrate 760. This step may benefit from high-energy implantation to increase depth of penetration of the dopants into the substrate 760 to create a heavily doped P+ region of the P+ common node 754. The high doping concentration is beneficial for reducing electrical resistance of the common node 754, improving charge collection and removal efficiency. After implantation, the substrate 760 may undergo an annealing process, typically in a rapid thermal annealer (RTA). Annealing at high temperatures allows the implanted dopants of the heavily-doped P+ region of the P+ common node 754 to become electrically active by moving them into substitutional lattice sites. This step can also repair damage to the silicon lattice caused by the implantation process, improving structural integrity of the substrate 760.

In the above description, the isolation structure 758 is formed, which is followed by formation of the guard ring 756, which is followed by formation of the sensing node 752, which is followed by formation of the common node 754. In some embodiments, one or more of the steps just described is performed in a different order than that described with reference to FIGS. 7A-7G. For example, the common node 754 may be formed prior to the sensing node 752. In another example, the guard ring 756 may be formed following formation of the common node 754.

In FIG. 7H, following formation of the isolation structure 758, guard ring 756, sensing node 752 and common node 754, the substrate 760 may be flipped in preparation to thin the substrate 760. In preparation for flipping the substrate 760, the front side 760f of the substrate 760, which contains the already fabricated devices or circuits, such as the isolation structure 758, the sensing node 752, the common node 754 and the guard ring 756, may be cleaned to remove any contaminants. This is beneficial to prevent damage or contamination during subsequent processing steps. Then, a handle wafer (not depicted for simplicity of illustration) can be prepared and bonded to the front side 760f of the substrate 760. The handle wafer serves as a mechanical support during a subsequent thinning process. A bonding material used may beneficially be strong enough to withstand the thinning process but also removable after the thinning process is completed. Materials such as temporary adhesives, glass-frit, or polymer-based bonding agents may be selected as the bonding material. After the bonding process, the substrate 760 is flipped so that the back side 760b is exposed and ready for thinning. The handle wafer, now bonded to the front side 760f, provides stability and protects the devices on the front side 760f during the thinning process.

In FIG. 7I, the substrate 760 is thinned by removing material of the substrate 760 from the back side thereof. For example, the exposed back side of the substrate 760 may be thinned to a selected thickness T1. This can be achieved through mechanical grinding, chemical mechanical polishing (CMP), or a combination of both. Mechanical grinding quickly removes the bulk of the material of the substrate 760, while CMP is used for fine polishing to achieve a smooth and uniform surface with the precise final thickness T1. The thinning process(es) can introduce stress and potential damage to the substrate 760. An optional stress relief step, such as gentle thermal annealing, may be performed to relieve stress and repair damage in the substrate material. Once the thinning process is completed and the substrate 760 is at the selected thickness T1, the handle wafer can be debonded from the front side of the substrate 760. Example debonding techniques can include one or more of heating, solvent dissolving, or mechanical force. After debonding, the substrate 760 can undergo a cleaning process to remove any residues from the bonding and debonding processes. In some embodiments, following the thinning process, the thickness or “height” T1 of the substrate 760 can be less than about 5 micrometers. The thickness T1 being below about 5 micrometers is beneficial to formation of the avalanche zone 766. Namely, thickness T1 that exceeds about 5 micrometers may result in insufficient formation of the avalanche zone 766, which may degrade operation of the image sensor 70.

In FIG. 7J, following thinning of the substrate 760, isolation extension structures 7600 are formed, corresponding to act 1060 of FIG. 9. The isolation extension structures 7600 may be similar in most respects to the isolation extension structures 5600, 60, 60A described with reference to FIGS. 5, 6A and 6B. In one example, a process for forming the isolation extension structures 7600 can begin with application of a photoresist to the silicon substrate 760. Photolithography is then used to pattern the photoresist, exposing areas where trenches are to be etched. An etching process, such as a reactive ion etching (RIE), can be used to create deep trenches in the silicon substrate 760. In some embodiments, the deep trenches expose the isolation structure(s) 758. After the trenches have been etched, a thin silicon oxide liner layer can be formed on the trench walls, corresponding to side surface isolation layers 762, which may be an embodiment of the side surface isolation layers 562, 662 described with reference to FIGS. 5 and 6B. Formation of the thin silicon oxide layer may be via thermal oxidation, where the substrate 760 is exposed to oxygen at high temperatures, causing a thin layer of silicon dioxide to grow on all silicon surfaces exposed by the deep trench. Alternatively, a CVD process can be used to deposit a uniform silicon oxide layer inside the trench. This method can be beneficial for improving uniformity of the oxide layer over complex topographies. To make contact with the underlying isolation structure 758 in selected areas, parts of the silicon oxide liner are removed. A selective etching process, such as a wet etch with hydrofluoric acid (HF) or a dry etch technique, can be used to remove the oxide layer without damaging the silicon substrate 760. Before conductive material of a conductive layer 764 is deposited, an optional barrier layer (e.g., titanium nitride) may be applied to prevent the conductive material from diffusing into the silicon substrate 760. The barrier layer can also promote adhesion of the conductive layer to the silicon oxide of the side surface isolation layer 562. The conductive material, such as tungsten, tantalum, or copper, is then deposited into the trench onto the isolation structure 758 and the side surface isolation layer 762. Deposition processes such as chemical vapor deposition (CVD) for tungsten, physical vapor deposition (PVD) for tantalum, or electrochemical deposition (ECD) for copper, or other suitable deposition processes, may be used depending on the material. For example, a CVD process can deposit tungsten hexafluoride (WF6), which is reduced to tungsten in the presence of hydrogen gas. A PVD process can sputter tantalum atoms onto surfaces exposed by the trench. An ECD process can plate copper onto the surfaces by cycling an electric current through a copper sulfate solution. After the deposition, excess conductive material of the conductive layer 764 and optionally the barrier layer are removed from the top surface of the silicon substrate 760, leaving a planar surface.

It should be noted that, although the above description of forming the isolation extension structure 7600 describes formation thereof following thinning of the substrate 760, in some embodiments, the isolation extension structure 7600 may be formed from the front side 760f of the substrate 760 prior to the thinning. For example, the deep trenches may be formed through the isolation structures 758 and extending to a depth below the isolation structures 758 that is less than about 2.5 micrometers. Then, the oxide layer 762 may be formed on exposed surfaces of the substrate 760 as described, followed by forming the conductive layer 764 on the oxide layer 762. When the substrate 760 is thinned, the thinning may stop on or after reaching the bottom surface of the isolation extension structure 7600. It should also be noted that, in the embodiment described above and the embodiment just described, formation of the side surface isolation layer 762 may be omitted, which would result in the isolation extension structure 60 described with reference to FIG. 6A. Namely, the conductive layer 764 may be in direct contact with the substrate 760 in some embodiments.

In FIG. 7K, following formation of the isolation extension structure 7600, a passivation layer 772 is formed on the back surface of the substrate 760 and exposed upper surfaces of the conductive layer 764 and optionally the side surface isolation layer 762, corresponding to act 1070 of FIG. 9. The passivation layer 772 may be similar in most respects to the passivation layer 572 described with reference to FIG. 5. The passivation layer 772 may cover an entire surface of the image sensor 70. Forming the passivation layer or protection layer 772 on the incident surface of the backside illuminated SPAD image sensor 70 is beneficial for protecting the image sensor 70 from environmental damage, reducing surface recombination, and enhancing photon detection efficiency. The incident surface in a BSI SPAD is the backside surface 760b through which photons enter. In one example process, cleaning of the backside surface 760b may be performed to remove any contaminants, residues, or particles therefrom. The cleaning may include a series of wet chemical cleans, such as RCA (Radio Corporation of America) clean, which can include a mixture of ammonium hydroxide (NH₄OH), hydrogen peroxide (H₂O₂), and water for organic residue removal, followed by a mixture of hydrochloric acid (HCl), H₂O₂, and water for metallic contaminant removal. An optional chemical mechanical polishing (CMP) step may be performed to improve smoothness and remove defects from the backside surface 760b. This can be beneficial to reduce surface irregularities that could reduce detection efficiency. Material of the passivation layer 772 can include SiN, SiC, SiON, SiO₂, SiCN, combinations thereof or the like. These materials may be beneficial at least for their chemical stability and ability to form high-quality interfaces with silicon of the substrate 760. The passivation layer 772 may be grown thermally in an oxidation furnace, deposited using CVD, such as plasma-enhanced CVD (PECVD), or deposited via another suitable process. The thickness of the passivation layer 772 can be beneficial to reduce absorption and reflection losses for the incident EUV photons. In some embodiments, for EUV light source intensity in a range of about 50 W/mm²Sr to about 200 W/mm²Sr, the thickness of the passivation layer 772 may exceed about 10 nm. In embodiments in which the EUV light source intensity is less than about 50 W/mm²Sr, the thickness of the passivation layer 772 may be less than about 5 nm. After deposition of the passivation layer 772, an annealing step may be performed to improve quality thereof by reducing defects and improving an interface between the passivation layer 772 and the silicon substrate 760. The annealing process can include heating the in-process device 70 to a selected temperature for a selected duration in a controlled atmosphere (e.g., nitrogen or forming gas).

Further in FIG. 7K, prior to or following the formation of the passivation layer 772, a multilayer reflector 770 is formed on the front side 760f of the substrate 760, corresponding to act 1080 of FIG. 9. The multilayer reflector 770 can include a stack of molybdenum/silicon (Mo/Si) bilayer pairs, which are selected for their high reflectivity at EUV wavelengths. An example process of forming the multilayer reflector 770 can involve a sequence of deposition operations to obtain a selected thickness and uniformity of each layer and overall thickness of the multilayer reflector 770. The process can begin with the preparation of the substrate 760. The substrate 760 may be cleaned to remove contaminants or particles that could interfere with the deposition process. The Mo/Si bilayers can be deposited using physical vapor deposition (PVD) methods such as magnetron sputtering or molecular beam epitaxy (MBE), which are beneficial for precise control over layer thickness and composition. The process can include alternating depositions of molybdenum (Mo) and silicon (Si) layers. The thickness of each layer may be selected to improve reflectivity at EUV wavelengths. In some embodiments, the silicon layer is about thicker than the molybdenum layer. As one example, the bilayer may include a silicon layer having thickness of about 4 nm and a molybdenum layer having thickness of about 1 nm. In some embodiments, the silicon and molybdenum layers have substantially the same thickness. For example, the silicon and molybdenum layers may each have thickness of about 3.5 nm. The total number of Mo/Si bilayer pairs in the stack can range from 5 to 40, but can be 50 or more in some embodiments. The stack may end with a silicon cap layer that is beneficial to protect the multilayer reflector 770 from oxidation and contamination. A capping layer, which may be a ruthenium (Ru) layer or another material layer that is resistant to oxidation and has suitable optical properties, may be deposited on top of the final silicon layer. The capping layer can protect the multilayer reflector 770 from degradation and enhances its durability and performance in the EUV lithography system. After deposition, the multilayer reflector 770 may undergo treatments such as annealing to improve crystallinity of the individual Si and Mo layers and further reduce interfacial roughness, which can enhance overall EUV reflectivity.

In FIG. 7L, following formation of the passivation layer 772 and the multilayer reflector 770, electrical contacts (e.g., conductive vias) 780, 782, 784f, 784b may be formed to provide electrical connection to various elements of the image sensor 70. A first contact 780 may extend through the multilayer reflector 770 and is electrically connected to (e.g., in direct contact with) the sensing node 752. A second contact 782 may extend through the multilayer reflector 770 and is electrically connected to (e.g., in direct contact with) the common node 754. A front side contact 784f may extend through the multilayer reflector 770 and the isolation structure 758 and be electrically connected to (e.g., in direct contact with) a first side of the conductive layer 764. A back side contact 784b may extend through the multilayer reflector 770 and the isolation structure 758 and be electrically connected to (e.g., in direct contact with) a second side of the conductive layer 764 that is opposite the first side. In embodiments in which the conductive layer 764 extends through the isolation structure 758, such as when the conductive layer 764 is formed from the front side 760f of the substrate 760 prior to thinning the substrate 760, the front side contact 784f can extend through the multilayer reflector 770 and land on the conductive layer 764 at or slightly below a level of the front side 760f of the substrate 760.

Formation of the contacts 780, 782, 784f can include a photolithography operation that patterns a mask layer, exposing regions of the multilayer reflector 770 where the contacts 780, 782, 784f will be formed. The exposed material may then be removed via a suitable etching or other removal process. The removal process removes the Si and Mo material in the areas exposed by the patterned mask layer, forming vias or holes that expose the underlying element, such as the sensor node 752, the common node 754 and the conductive layer 764. Alternatively, a focused ion beam (FIB) or laser ablation may be utilized to form the contact holes through the Si and Mo layers of the multilayer reflector 770.

The holes are then filled with a conductive metal to establish the electrical contact. The conductive metal may be or include copper, tungsten, aluminum or the like. The metal fill can be performed through various methods, including electrochemical plating (ECP) for copper, CVD for tungsten, or another suitable deposition process. After the metal fill, the surface of the multilayer reflector 770 may be planarized using chemical mechanical polishing to remove any excess metal and ensure a flat surface for subsequent processing steps. This leaves the metal only in the contact holes, forming a smooth, level surface with the multilayer reflector 770. In some embodiments, to avoid electrical shorting between the contacts 780, 782, 784f that extend through the molybdenum layers of the multilayer reflector 770, dielectric liner layers or spacer layers may be formed in the contact holes associated with the contacts 780, 782, 784f prior to deposition of conductive material of the contacts 780, 782, 784f. The dielectric liner layers may include one or more dielectric materials, such as SiN, SiC, SiON, SiO₂, SiCN or the like.

In FIG. 7M, an SOC 900 is attached to the image sensor 70. The SOC 900 may be an embodiment of the SOC 500 of FIG. 5. The SOC 900 may include a first pad 730 and a second pad 740 on a surface thereof. The first pad 730 may be electrically connected to the second contact 782 via an interconnect structure 790. The interconnect structure 790 may be or include one or more conductive vias and conductive traces that are formed in different metal layers embedded in one or more dielectric layers. The interconnect structure 790 may form a local interconnect between the first pad 730 and the second contact 782 through the SOC 900.

The SOC 900 may include an interconnect structure 792 that electrically connects the second pad 740 to a contact metal 798 on an opposite side of the SOC 900. The SOC 900 may also include an interconnect structure 794 that electrically connects the first contact 780 to a contact metal 796 on the opposite side of the SOC 900. The interconnect structures 790, 792 and the contact metals 796, 798 may be or include one or more conductive materials, such as copper, tungsten, aluminum, tantalum, ruthenium, cobalt or the like.

In FIG. 7N, an integrated circuit (IC) 910 is attached to the SOC 900. The integrated circuit 910 is an embodiment of the integrated circuit 510 described with reference to FIG. 5 and may be similar in most respects thereto. The integrated circuit 910 includes an interconnect structure 804 that electrically connects the second pad 740 to the first contact 780. When the IC 910 is attached to the SOC 900, the IC 910 and the SOC 900 may be bonded to each other. For example, the contact metal 798 of the SOC 900 may be bonded to a metal feature of the IC 910 to form a metal bond 802 and the contact metal 796 of the SOC 900 may be bonded to a metal feature of the IC 910 to form another metal bond 800. Electrical connection between the second pad 740 and the first contact 780 may be via the interconnect structure 792, the metal bond 802, the interconnect structure 804, the metal bond 800 and the interconnect structure 794. The interconnect structure 804 and metal features of the IC 910 may be or include one or more conductive materials, such as copper, tungsten, aluminum, tantalum, ruthenium, cobalt or the like.

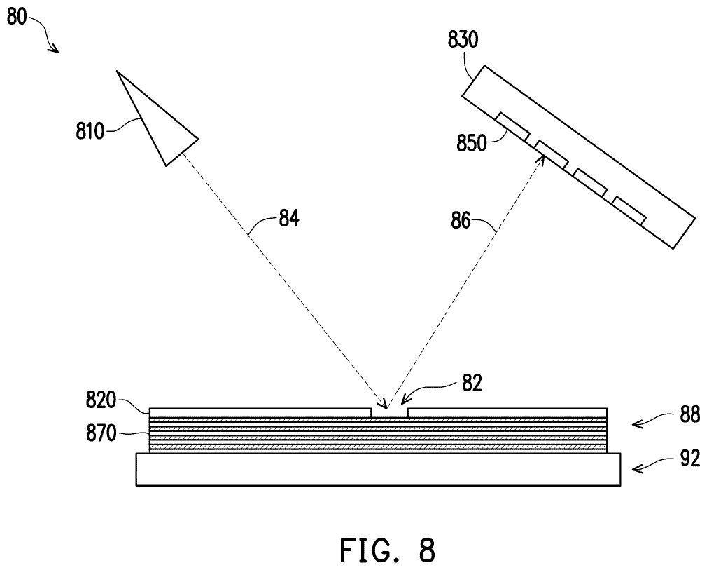

FIG. 8 is a diagrammatic view of a system 80 in accordance with various embodiments. The system 80 may be an inspection system 80 or a monitoring system 80 that can detect photons of incoming light 86 that is reflected when an EUV photomask 88 secured by a mask stage 92 is exposed to EUV light 84 generated by an EUV light source 810. FIG. 10 is a flowchart of a method 2000 that may be performed by the system 80. In some embodiments, the method 2000 may be performed by a system having additional, fewer and/or different elements than the system 80.

The light source 810 is configured to generate light radiation having a wavelength ranging between about 1 nm and about 300 nm in certain embodiments. In one particular example, the light source 810 generates EUV radiation with a wavelength centered at about or substantially 13.5 nm. Accordingly, the light source 810 is also referred to as an EUV radiation source. However, it should be appreciated that the light source 810 is not limited to emitting EUV radiation. The light source 810 can be utilized to perform any high-intensity photon emission from excited target fuel.

The mask stage 92 is configured to secure the mask 88. In some embodiments, the mask stage 92 includes an electrostatic chuck (e-chuck) to secure the mask 88. One reason an e-chuck is beneficial is that gas molecules absorb EUV radiation and the e-chuck is operable in a lithography exposure system for EUV lithography patterning or inspection that is maintained in a vacuum environment to avoid EUV intensity loss. The terms mask, photomask, and reticle may be used interchangeably. The mask 88 is a reflective mask. One example structure of the mask 88 includes a substrate with a suitable material, such as a low thermal expansion material (LTEM) or fused quartz. In various examples, the LTEM includes TiO₂ doped SiO₂, or other suitable materials with low thermal expansion. The mask 88 includes a reflective multilayer 870 deposited on the substrate. The mask stage 92 is operable to translate in two horizontal directions so as to expose multiple different regions of the mask 88 to the EUV 84. The reflective multilayer 870 or multilayer reflector 870 may be similar in many respects to the multilayer reflector 770 and may include additional elements, such as an absorber layer 820 that has openings 82 therein that expose regions of the reflective multilayer 870 according to a pattern.

The system 80 detects the photons of the light 86 via an image sensor 830 that includes a plurality of SPADs 850. The image sensor 830 may be any of the image sensors 10, 10A, 10B, 40, 50, 70 described with reference to FIGS. 1A, 1B, 1C, 4, 5 and 7A-7N.

In act 2010 of the method 2000, a photon of an EUV wavelength can be generated by a light source, such as the light source 810 described with reference to FIG. 8. The photon may be received at a back side of a substrate, such as the substrate 560, 660, 760 described with reference to FIGS. 5, 6A, 6B, and 7A-7N.

Then, in act 2020 of the method 2000, avalanche current may be generated in response to the photon. For example, the photon may be received by a photon detector (e.g., a SPAD 550) in the substrate 560. The photon may excite an electron, which may travel toward a sensing node of the photon detector as described with reference to FIG. 5. The photon may pass through a passivation layer (e.g., the passivation layer 772) on a back side of the substrate. When intensity of the EUV light 84 is less than 50 W/mm²Sr, the passivation layer on the back side of the substrate may have thickness less than about 5 nanometers. When intensity of the EUV light 84 that includes the photon exceeds 50 W/mm²Sr and is less than 200 W/mm²Sr the passivation layer on the back side of the substrate has thickness that exceeds about 10 nanometers.

Then, in act 2030 of the method 2000, the avalanche current is detected. For example, the avalanche current may be detected via the SOC 500, 900 and/or the IC 510, 910 described with reference to FIGS. 5 and 9. The avalanche current may flow between the sensor node 752 and the common node 754, and may be detected via the pads 730, 740 that are electrically connected to the sensor and common nodes 752, 754. In some embodiments, the avalanche current is detected by circuitry internal to the SOC 500, 900 without the IC 510, 910 performing detection.

Embodiments may provide advantages. SPAD photon counting can mitigate against gain noise and circuit noise due to detector response being binarized. The EUV SPAD of the embodiments operates on EUV light having bandwidth of 13.5 nm, which can increase efficiency. Use of the multilayer reflector can improve collection of photons into the avalanche zone. An isolation extension structure that includes a conductive layer carrying a voltage bias can also improve flow of electrons to the sensor node.

One general embodiment includes a method. The method includes forming a doped substrate by doping a substrate with a first dopant species. The method also includes forming an isolation structure in a front side of the doped substrate. The method also includes forming an isolation extension structure that extends from a back side of the doped substrate to the isolation structure. The method also includes forming a guard ring adjacent the isolation structure in the front side of the doped substrate, the guard ring including the first dopant species. The method also includes forming a sensing node adjacent to the guard ring, the guard ring being between the sensing node and the isolation structure, the sensing node including a second dopant species of a different type than the first dopant species. The method also includes forming a common node in the front side of the doped substrate, the common node being positioned between the isolation structure and the guard ring, the common node including the first dopant species. The method also includes forming a multilayer reflector on the front side of the substrate.

One general aspect includes a device that includes a photon detector and a substrate. The device also includes an isolation structure in a first side of the substrate. The device also includes a guard ring adjacent the isolation structure and in the first side of the substrate. The device also includes a sensor node in the first side of the substrate, the guard ring being between the sensor node and the isolation structure. The device also includes a common node in the first side of the substrate, the common node being between the guard ring and the isolation structure. The device also includes an isolation extension structure in a second side of the substrate opposite the first side, the isolation extension structure extending from the second side to the isolation structure. The device also includes a multilayer reflector on the first side of the substrate.

One general aspect includes a method that includes receiving a photon of an extreme ultraviolet wavelength at a back side of a substrate. The method also includes receiving the photon by a photon detector in the substrate, a multilayer reflector being attached to a front side of the substrate. The method also includes detecting the photon by generating an avalanche current in response to the photon.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a doped substrate by doping a substrate with a first dopant species;
forming an isolation structure in a front side of the doped substrate;
forming an isolation extension structure that extends from a back side of the doped substrate to the isolation structure;
forming a guard ring adjacent the isolation structure in the front side of the doped substrate, the guard ring including the first dopant species;
forming a sensing node adjacent to the guard ring, the guard ring being between the sensing node and the isolation structure, the sensing node including a second dopant species of a different type than the first dopant species;
forming a common node in the front side of the doped substrate, the common node being positioned between the isolation structure and the guard ring, the common node including the first dopant species; and
forming a multilayer reflector on the front side of the substrate.

2. The method of claim 1, further comprising:
forming a passivation layer on a back side of the doped substrate, the passivation layer including a dielectric material.

3. The method of claim 2, wherein the forming a passivation layer includes forming the passivation layer having thickness that exceeds about 10 nanometers.

4. The method of claim 1, wherein the forming an isolation extension structure includes forming a conductive layer that has height less than about 2.5 micrometers.

5. The method of claim 4, wherein the forming an isolation extension structure further includes forming electrical contacts on opposite sides of the conductive layer.

6. The method of claim 1, further comprising forming a side wall insulator layer between the doped substrate and the isolation extension structure.

7. The method of claim 1, wherein the forming an isolation extension structure includes forming the isolation extension structure having a conductive layer laterally abutted by oxide layers on opposite sides thereof.

8. The method of claim 1, further comprising:
forming a first contact that extends through the multilayer reflector and is electrically connected to the sensing node; and
forming a second contact that extends through the multilayer reflector and is electrically connected to the common node.

9. The method of claim 6, further comprising:
attaching a system-on-a-chip (SOC) substrate to the multilayer reflector; and
attaching an integrated circuit to the SOC substrate.

10. The method of claim 1, wherein the forming a multilayer reflector includes forming a plurality of bilayers each including a molybdenum layer and a silicon layer, each of the molybdenum layers and the silicon layers having thickness in a range of about 3 nanometers to about 4 nanometers and a number of the plurality of bilayers being in a range of about 5 to about 40.

11. A device comprising:
a photon detector including:
a substrate;
an isolation structure in a first side of the substrate;
a guard ring adjacent the isolation structure and in the first side of the substrate;
a sensor node in the first side of the substrate, the guard ring being between the sensor node and the isolation structure;
a common node in the first side of the substrate, the common node being between the guard ring and the isolation structure; and
an isolation extension structure in a second side of the substrate opposite the first side, the isolation extension structure extending from the second side to the isolation structure; and
a multilayer reflector on the first side of the substrate.

12. The device of claim 11, further comprising:
a dielectric layer between the isolation extension structure and the substrate.

13. The device of claim 11, wherein the isolation extension structure includes:
a conductive layer;
a front side contact on the conductive layer; and
a second side contact on the conductive layer.

14. The device of claim 11, further comprising:
a first contact that extends through the multilayer reflector and is electrically connected to the sensing node; and
a second contact that extends through the multilayer reflector and is electrically connected to the common node.

15. The device of claim 14, further comprising:
a system-on-a-chip (SOC) attached to the multilayer reflector, the SOC including:
a first pad on a surface of the SOC, the first pad being electrically connected to the sensing node via the first contact; and
a second pad on the surface of the SOC, the second pad being electrically connected to the common node via the second contact.

16. The device of claim 15, further comprising:
an integrated circuit die attached to the SOC, wherein the first pad is electrically connected to the first contact via the integrated circuit die.

17. A method, comprising:
receiving a photon of an extreme ultraviolet wavelength at a back side of a substrate;
receiving the photon by a photon detector in the substrate, a multilayer reflector being attached to a front side of the substrate; and
detecting the photon by generating an avalanche current in response to the photon.

18. The method of claim 17, wherein the receiving the photon includes the photon passing through a passivation layer on a back side of the substrate.

19. The device of claim 18, wherein the passivation layer on the back side of the substrate has thickness less than about 5 nanometers when intensity of extreme ultraviolet light including the photon is less than 50 W/mm²Sr.

20. The device of claim 18, wherein the passivation layer on the back side of the substrate has thickness that exceeds about 10 nanometers when intensity of extreme ultraviolet light including the photon exceeds 50 W/mm²Sr and is less than 200 W/mm²Sr.
